(19) United States
(12) Patent Application Publication
(10) Pub. No.: US 2024/0402289 A1
(43) Pub. Date: Dec. 5, 2024

(54) 2D PHASED SUBARRAY MIMO RADAR

(71) Applicant: Korea Advanced Institute of Science and Technology, Daejeon (KR)

(72) Inventors: Song Cheol Hong, Daejeon (KR); Kawon Han, Daejeon (KR); Seonghyeon Kang, Daejeon (KR)

(21) Appl. No.: 18/651,199

(22) Filed: Apr. 30, 2024

(30) Foreign Application Priority Data
May 31, 2023 (KR) 10-2023-0070238

(51) Int. Cl. G01S 7/03; G01S 13/02

(52) U.S. Cl. CPC G01S 7/032; G01S 2013/0263

(57) ABSTRACT

A two-dimensional phased subarray MIMO radar apparatus includes a transmission array and a reception array. The transmission array is configured to emit transmission signals, which are orthogonal to each other, towards a target object and extends in a first direction. Moreover, the transmission array includes a plurality of transmission phased subarrays. The reception array is configured to receive reflected signals, which are reflected from the target object, among the emitted transmission signals and extends in a second direction intersecting the first direction. Moreover, the reception array includes a plurality of reception phased subarrays. Each of the plurality of transmission phased subarrays includes a plurality of transmission antennas. Each of the plurality of reception phased subarrays includes a plurality of reception antennas. A first transmission phased subarray and a second transmission phased subarray are adjacent transmission phased subarrays among the plurality of transmission phased subarrays. A spacing from an end of the first transmission phased subarray in the first direction to an end of the second transmission phased subarray in the first direction is a first spacing. The first spacing is greater than or equal to an aperture of each of the plurality of transmission phased subarrays.

### CROSS-REFERENCE TO RELATED APPLICATION

The present application claims priority from Korean Patent Application No. 10-2023-0070238, filed on May 31, 2023, in the Korean Intellectual Property Office, the disclosure of which is incorporated herein in its entirety by reference.

### BACKGROUND

### 1. Field

The present disclosure relates to a MIMO (Multiple Input Multiple Output) radar, more specifically to a two-dimensional phased subarray MIMO radar with improved sensitivity and resolution by arranging a plurality of phased subarrays in two dimensions and increasing the spacing between the phased subarrays.

### 2. Description of Related Art

With improved performance and broader range of applications, radars are attracting attention as a key technology for advanced sensors. For instance, there are many ongoing studies for radar technologies that are applicable in various fields such as autonomous vehicle safety systems, collection of human biometric information, and smart building security. Today, radars are evolving in the direction of reducing the hardware size while improving spatial resolution (e.g., spatial resolution, angular resolution).

A large number of antennas (multiple antennas) are required to implement a radar with high resolution. Proposed to achieve this has been a MIMO radar that forms a virtual receiver array. The virtual receiver array of a MIMO radar refers to a technique for virtually expanding multiple antennas. That is, by forming a virtual receiver array, the mutual interference of the received signals may be minimized, and more accurate information may be extracted. Through this, it is possible to implement a MIMO radar with higher resolution and signal strength.

To implement the above-described MIMO radar, it is advantageous to arrange the antennas based on the half-wavelength (e.g., to allow the spacing between the antennas to be half the signal wavelength used in the MIMO radar). This is because, by arranging the antennas based on the half-wavelength, the interference between antenna elements may be minimized, and thus the spatial resolution may be improved by using more antenna elements.

At the same time, there have been MIMO radars developed recently that use higher frequencies than conventional frequencies in order to process more data. Using higher frequency signals in the MIMO radar may yield certain advantages, including an improved spatial resolution and more information transferred. However, it becomes quite challenging to arrange the antennas based on half-wavelength.

The spacing between the antennas plays an important role in the resolution and performance of the MIMO radar. This is because the resolution and performance may be degraded when the spacing between the antennas is too narrow or too wide. Meanwhile, as the frequency of the signal used becomes higher, the size of the integrated circuit (for amplifying and distributing the signal inputted into the antenna) of the MIMO radar becomes bigger than the size of a single antenna. For this reason, the higher the frequency of the signal, the more difficult it becomes to arrange multiple antennas due to the increased size of the integrated circuit.

Accordingly, there is a demand for technological development for an efficient antenna array structure that can arrange multiple antennas while using higher frequency signals.

### SUMMARY

Contrived to solve the above-described shortcomings of the conventional art, an object of the present disclosure is to provide a two-dimensional phased subarray MIMO radar with improved sensitivity and resolution by arranging a plurality of phased subarrays in two dimensions and increasing the spacing between the plurality of phased subarrays.

Moreover, the present disclosure aims to provide a two-dimensional phased subarray MIMO radar with improved resolution by cancelling the grating lobes that occur during the process of increasing the spacing between the plurality of phased subarrays through RF beamforming.

Furthermore, the present disclosure aims to provide a two-dimensional phased subarray MIMO radar the technical requirements of users by providing various embodiments in which transmitting antennas and/or receiving antennas are added or omitted.

A two-dimensional phased subarray MIMO radar apparatus in accordance with an embodiment of the present disclosure may include a transmission array and a reception array.

The transmission array may be configured to emit transmission signals that are orthogonal to each other towards a target. Moreover, the transmission array may extend in a first direction and include a plurality of transmission phased subarrays.

The reception array may be configured to receive reflected signals, which are reflected from the target, among the emitted transmission signals. Moreover, the reception array may extend in a second direction, which intersects the first direction, and include a plurality of reception phased subarrays.

Each of the plurality of transmission phased subarrays may include a plurality of transmission antennas. Each of the plurality of reception phased subarrays may include a plurality of reception antennas.

A first transmission phased subarray and a second transmission phased subarray may be adjacent transmission phased subarrays among the plurality of transmission phased subarrays. The spacing from an end of the first transmission phased subarray in the first direction to an end of the second transmission phased subarray in the first direction may be a first spacing. The first spacing may be greater than or equal to an aperture of each of the plurality of transmission phased subarrays.

A first reception phased subarray and a second reception phased subarray may be adjacent reception phased subarrays among the plurality of reception phased subarrays. The spacing from an end of the first reception phased subarray in the second direction to an end of the second reception phased subarray in the second direction may be a second spacing. The second spacing may be greater than or equal to an aperture of each of the plurality of reception phased subarrays.

In the two-dimensional phased subarray MIMO radar apparatus in accordance with an embodiment of the present disclosure, the transmission array may be provided in plurality. The plurality of transmission arrays may be arranged to be spaced apart from each other and face each other. A first transmission array and a second transmission array may each be one of the plurality of transmission arrays. The first transmission array and the second transmission array may be arranged to be spaced apart from each other by the size of an aperture of the reception array.

In the two-dimensional phased subarray MIMO radar apparatus in accordance with an embodiment of the present disclosure, the reception array may be provided in plurality. The plurality of reception arrays may be arranged to be spaced apart from each other and face each other. A first reception array and a second reception array may each be one of the plurality of reception arrays. The first reception array and the second reception array may be arranged to be spaced apart from each other by the size of an aperture of the transmission array.

In the two-dimensional phased subarray MIMO radar apparatus in accordance with an embodiment of the present disclosure, the transmission array and the reception array may each be provided in plurality. The plurality of transmission arrays may be arranged to be spaced apart from each other and face each other. The plurality of reception arrays may be arranged to be spaced apart from each other and face each other.

A first transmission array and a second transmission array may each be one of the plurality of transmission arrays. A first reception array and a second reception array may each be one of the plurality of reception arrays. The first transmission array and the second transmission array may have the same size of aperture. The first reception array and the second reception array may have the same size of aperture.

The first transmission array and the second transmission array may be arranged to be spaced apart from each other by the size of the aperture of the first reception array. The first reception array and the second reception array may be arranged to be spaced apart from each other by the size of the aperture of the first transmission array.

The two-dimensional phased subarray MIMO radar apparatus in accordance with an embodiment of the present disclosure may include a transmission circuit and a reception circuit.

The transmission circuit may include a plurality of first phase shifters corresponding, respectively, to the plurality of transmission antennas. The transmission circuit may perform hybrid beamforming by steering a transmission subarray beam pattern of the plurality of transmission phased subarrays based on weights applied to the plurality of first phase shifters.

The reception circuit may include a plurality of second phase shifters corresponding, respectively, to the plurality of reception antennas. The reception circuit may perform hybrid beamforming by steering a reception subarray beam pattern of the plurality of reception phased subarrays based on weights applied to the plurality of second phase shifters.

The two-dimensional phased subarray MIMO radar apparatus in accordance with an embodiment of the present disclosure may further include a control circuit.

The control circuit may be configured to generate an input digital signal, a first control signal for controlling the transmission circuit and a second control signal for controlling the reception circuit.

The transmission circuit may further include a plurality of digital-to-analog converters and a plurality of first mixers.

The plurality of digital-to-analog converters may correspond, respectively, to the plurality of transmission phased subarrays. Moreover, the plurality of digital-to-analog converters may be configured to convert the input digital signal to first baseband signals, which are analog signals.

The plurality of first mixers may correspond, respectively, to the plurality of transmission phased subarrays. Moreover, the plurality of first mixers may be configured to convert each of the first baseband signals to a high-frequency RF signal. Each of the plurality of first phase shifters may be configured to delay the phase of the RF signal based on the first control signal before providing the RF signal to one of the plurality of transmission antennas.

The reception circuit may further include a plurality of analog-to-digital converters and a plurality of second mixers.

Each of the plurality of second phase shifters may be configured to delay the phase of the reflected signals based on the second control signal and then provide the reflected signals to the plurality of second mixers.

The plurality of second mixers may correspond, respectively, to the plurality of reception phased subarrays. Moreover, the plurality of second mixers may be configured to convert the delayed reflected signals to second baseband signals.

The plurality of analog-to-digital converters may correspond, respectively, to the plurality of reception phased subarrays. Moreover, the plurality of analog-to-digital converters may be configured to convert the second baseband signals, which are analog signals, to output digital signals.

In the two-dimensional phased subarray MIMO radar apparatus in accordance with an embodiment of the present disclosure, the number of the transmission antennas and the reception antennas may each be M. The number of the transmission phased subarrays may be P. The number of the reception phased subarrays may be Q. Here, M, P and Q may each be an integer greater than or equal to 2.

Based on the second baseband signals, 2P*2M virtual reception phased subarrays may be formed in a matrix format. Each of the virtual reception phased subarrays may include M*M virtual reception antennas. A virtual subarray beam pattern may be formed in the virtual reception phased subarrays.

The transmission circuit may be configured to steer the transmission subarray beam pattern in a first steering direction, and the reception circuit may be configured to steer the reception subarray beam pattern in a second steering direction, thereby cancelling some of grating lobes occurred in the virtual subarray beam pattern.

In the two-dimensional phased subarray MIMO radar apparatus in accordance with an embodiment of the present disclosure, a first grating lobe and a second grating lobe may each be one of the grating lobes adjacent to a main lobe of the virtual subarray beam pattern.

The transmission circuit may align a direction of a first null point occurred in the transmission subarray beam pattern with a direction of the first grating lobe. Moreover, the reception circuit may align a direction of a second null point occurred in the reception subarray beam pattern with a direction of the second grating lobe of the grating lobes. Through this process, the transmission circuit and the reception circuit may cancel some of the first and second grating lobes.

In the two-dimensional phased subarray MIMO radar apparatus in accordance with an embodiment of the present disclosure, the spacing between two adjacent transmission antennas among the plurality of transmission antennas and the spacing between two adjacent reception antennas among the plurality of reception antennas may each be equal to a half-wavelength of the transmission signals.

In the two-dimensional phased subarray MIMO radar apparatus in accordance with an embodiment of the present disclosure, the transmission array and the reception array may each be provided in plurality.

The plurality of transmission arrays may be arranged to be spaced apart from each other and face each other. The plurality of reception arrays may be arranged to be spaced apart from each other and face each other. The plurality of transmission arrays may have the same size of aperture. The plurality of reception arrays may have the same size of aperture. Two adjacent transmission arrays among the plurality of transmission arrays may be arranged to be spaced apart from each other by the size of the aperture of the reception array. Two adjacent reception arrays among the plurality of reception arrays may be arranged to be spaced apart from each other by the size of the aperture of the transmission array.

According to an embodiment of the present disclosure, a two-dimensional phased subarray MIMO radar with improved sensitivity and resolution may be provided by arranging a plurality of phased subarrays in two dimensions and increasing the spacing between the plurality of phased subarrays.

According to an embodiment of the present disclosure, a two-dimensional phased subarray MIMO radar with improved sensitivity may be provided by cancelling the grating lobes occurring while increasing the spacing between the plurality of phased subarrays through RF beamforming.

Moreover, it is possible to provide a two-dimensional phased subarray MIMO radar meeting the technical requirements of users by offering various embodiments in which transmission antennas and/or reception antennas are added or omitted.

### BRIEF DESCRIPTION OF THE DRAWINGS

FIG. 1 illustrates an exemplary block diagram of a two-dimensional phased subarray MIMO radar apparatus in accordance with an embodiment of the present disclosure.

FIG. 2 illustrates a portion of the two-dimensional phased subarray MIMO radar apparatus in accordance with an embodiment of the present disclosure.

FIG. 3 illustrates a portion of a two-dimensional phased subarray MIMO radar apparatus in accordance with another embodiment of the present disclosure.

FIG. 4 illustrates a portion of a two-dimensional phased subarray MIMO radar apparatus in accordance with yet another embodiment of the present disclosure.

FIG. 5 illustrates a portion of a two-dimensional phased subarray MIMO radar apparatus in accordance with still another embodiment of the present disclosure.

FIG. 6 illustrates a portion of the transmission array and transmission circuit of the two-dimensional phased subarray MIMO radar apparatus in accordance with an embodiment of the present disclosure.

FIG. 7 illustrates a portion of the reception array and reception circuit of the two-dimensional phased subarray MIMO radar apparatus in accordance with an embodiment of the present disclosure.

FIG. 8 illustrates a plurality of virtual reception phased subarrays generated by the two-dimensional phased subarray MIMO radar apparatus in accordance with an embodiment of the present disclosure.

### DETAILED DESCRIPTION

Hereinafter, certain preferred embodiments of the present disclosure will be described with reference to the accompanied drawings. In the drawings, the proportions and dimensions of the elements may be exaggerated for effective description of the technical details.

Throughout the description, it shall be appreciated that terms such as “comprise,” “comprising,” “include” and “including” are intended to specify that there are certain features, numbers, steps, actions, elements, components, or any combination thereof described in the specification and not to exclude the possibility of presence or addition of one or more of other features, numbers, steps, actions, elements, components or any combination thereof.

Moreover, when a certain element is described to be “on” another element, it shall be appreciated that the particular element is above or below the other element and not necessarily located on an upper side of the other element in the gravitational direction.

Moreover, when an element is described to be “connected” or “coupled” to another element, it shall be appreciated that the particular element may not only be directly connected or coupled to the other element but also be indirectly connected or coupled to the other element by way of yet another element.

Moreover, while terms such as “first,” “second,” etc. may be used in describing an element, it shall be appreciated that these terms are used merely for distinguishing one element from other elements and not for defining the nature, order or sequence of the element.

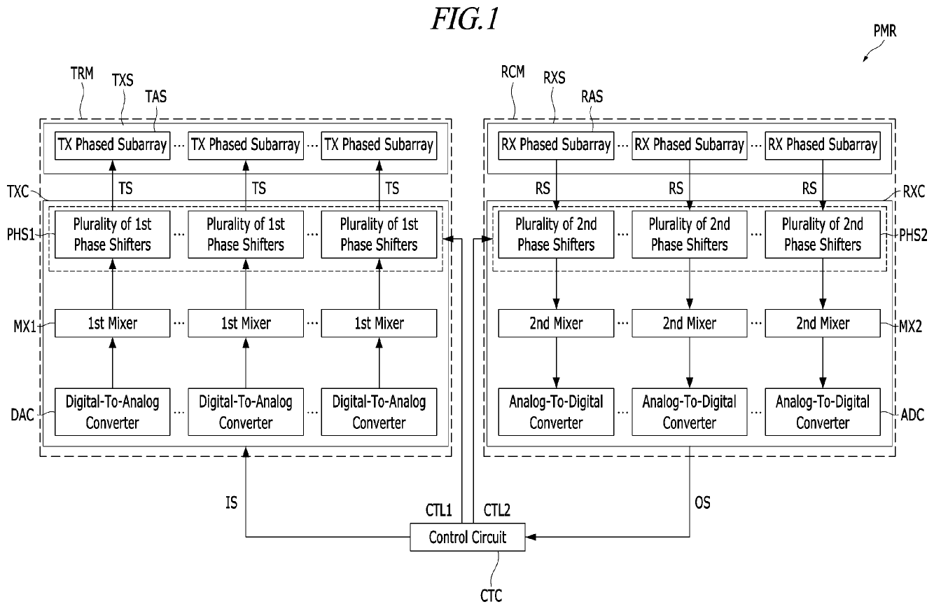

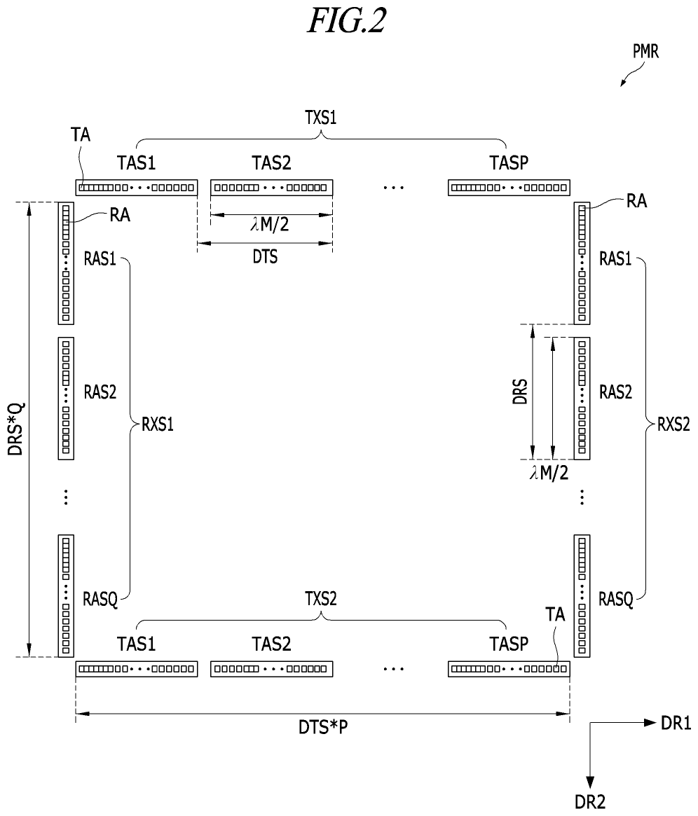

FIG. 1 illustrates an exemplary block diagram of a two-dimensional phased subarray MIMO radar apparatus PMR in accordance with an embodiment of the present disclosure. FIG. 2 illustrates a portion of the two-dimensional phased subarray MIMO radar apparatus PMR in accordance with an embodiment of the present disclosure.

Referring to FIG. 1 and FIG. 2, the two-dimensional phased subarray MIMO radar apparatus PMR may include a control circuit CTC, a transmission device TRM and a reception device RCM.

The control circuit CTC may be configured to control a transmission circuit TXC and a reception circuit RXC. The control circuit CTC may be configured to generate an input digital signal IS, a first control signal CTL1 and a second control signal CTL2. The input digital signal IS may be for generating transmission signals TS. The control circuit CTC may be configured to provide the input digital signal IS to the transmission circuit TXC. The first control signal CTL1 may be for controlling the transmission circuit TXC. The control circuit CTC may be configured to provide the first control signal CTL1 to the transmission circuit TXC. The second control signal CTL2 may be for controlling the reception circuit RXC. The control circuit CTC may be configured to provide the second control signal CTL2 to the reception circuit RXC. In an embodiment of the present disclosure, the control circuit CTC may be omitted.

The transmission device TRM may include the transmission circuit TXC and a transmission array TXS.

The transmission circuit TXC may be configured to convert the input digital signal IS to first baseband signals BS1, which are analog signals, based on the first control signal CTL1. Moreover, the transmission circuit TXC may be configured to convert the first baseband signals BS1 to transmission signals TS, which are high frequency signals. The transmission circuit TXC may be configured to provide the transmission signals TS to the transmission array TXS. In an embodiment of the present disclosure, the transmission circuit TXC may be omitted.

The transmission array TXS may be configured to emit the transmission signals TS that are orthogonal to each other towards a target object. The transmission signals TS may be Radio Frequency signals that are orthogonal to each other. The transmission array TXS may extend in a first direction DR1. The transmission array TXS may include a plurality of transmission phased subarrays TAS1, TAS2, . . . , TASP.

The plurality of transmission phased subarrays TAS1, TAS2, . . . , TASP may each include a plurality of transmission antennas TA1, TA2, . . . , TAM. In an embodiment of the present disclosure, the spacing between two adjacent transmission antennas TA of the plurality of transmission antennas TA1, TA2, . . . , TAM may be equal to a half-wavelength (λ/2) of the transmission signals TS.

A first transmission phased subarray TAS1 and a second transmission phased subarray TAS2 may be adjacent transmission phased subarrays among the plurality of transmission phased subarrays TAS1, TAS2, . . . , TASP. The spacing from an end of the first transmission phased subarray TAS1 in the first direction DR1 to an end of the second transmission phased subarray TAS2 in the first direction DR1 may be a first spacing DTS. The first spacing DTS may be greater than or equal to an aperture (λM/2) of each of the plurality of transmission phased subarrays TAS1, TAS2, . . . , TASP.

The reception device RCM may include a reception array RXS and the reception circuit RXC.

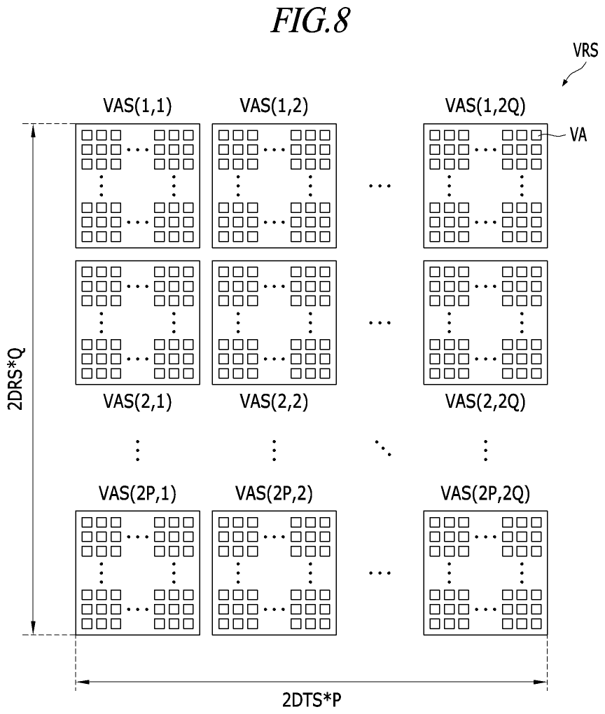

The reception circuit RXC may be configured to convert reflected signals RS to second baseband signals BS2 based on the second control signal CTL2. Moreover, the reception circuit RXC may be configured to convert the second baseband signals BS2 to output digital signals OS, which are digital signals. The reception circuit RXC may be configured to provide the output digital signals OS to the control circuit CTC. The reception circuit RXC may be configured to form a plurality of virtual reception phased subarrays VAS, each of which included a plurality of virtual reception antennas VA, based on the second baseband signals BS2. The plurality of virtual reception phased subarrays VAS may be configured to form a virtual subarray beam pattern by separating signal components that are orthogonal to each other from the second baseband signals BS2. This will be described in detail with reference to FIG. 8. In an embodiment of the present disclosure, the reception circuit RXC may be omitted.

The reception array RXS may be configured to receive, among the emitted transmission signals TS, the reflected signals RS that are reflected from the target object. The reception array RXS may extend in a second direction DR2, which intersects the first direction DR1. The reception array RXS may include a plurality of reception phased subarrays RAS1, RAS2, . . . , RASQ.

The plurality of reception phased subarrays RAS1, RAS2, . . . , RASQ may each include a plurality of reception antennas RA1, RA2, . . . , RAM. In an embodiment of the present disclosure, the spacing between two adjacent reception antennas RA of the plurality of reception antennas RA1, RA2, . . . , RAM may be equal to a half-wavelength (λ/2) of the transmission signals TS.

The plurality of transmission phased subarrays TAS1, TAS2, . . . , TASP and the plurality of reception phased subarrays RAS1, RAS2, . . . , RASQ may be configured to successively scan in a plurality of steering directions and detect the target object.

A first reception phased subarray RAS1 and a second reception phased subarray RAS2 may be adjacent reception phased subarrays among the plurality of reception phased subarrays RAS1, RAS2, . . . , RASQ. The spacing from an end of the first reception phased subarray RAS1 in the second direction DR2 to an end of the second reception phased subarray RAS2 in the second direction DR2 may be a second spacing DRS. The second spacing DRS may be greater than or equal to an aperture (λM/2) of each of the plurality of reception phased subarrays RAS1, RAS2, . . . , RASQ.

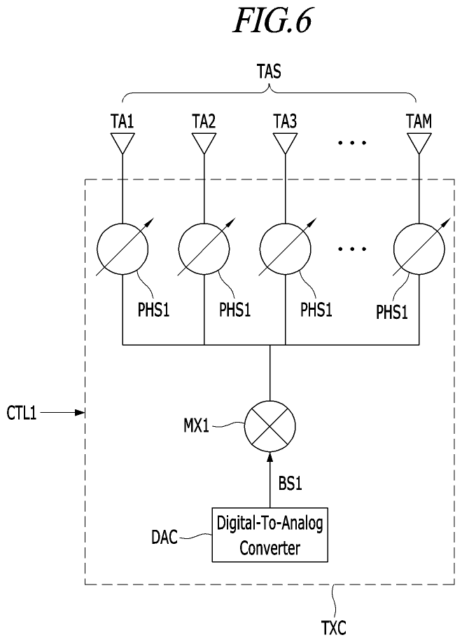

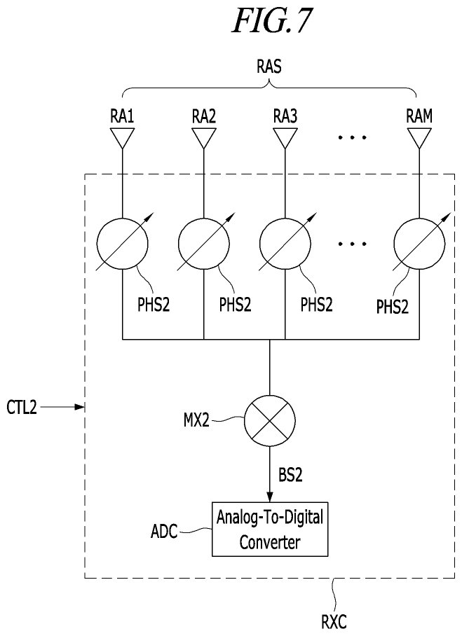

In other words, in the two-dimensional phased subarray MIMO radar apparatus PMR in accordance with an embodiment of the present disclosure, the spacing between the plurality of transmission phased subarrays TAS1, TAS2, . . . , TASP and the spacing between the plurality of reception phased subarrays RAS1, RAS2, . . . , RASQ may be adjusted to expand the antenna aperture, resulting in improved angular resolution. However, the performance of estimating the location of the target object may be deteriorated by grating lobes occurring in the virtual subarray beam pattern. The control circuit CTC may cancel some of the grating lobes occurring in the virtual subarray beam pattern by controlling the transmission circuit TXC and the reception circuit RXC based on the first control signal CTL1 and the second control signal CTL2. This will be described in detail with reference to FIGS. 6 and 7.

Referring to FIG. 2, the transmission array TXS and the reception array RXS may each be provided in plurality. Moreover, a plurality of transmission arrays TXS1, TXS2 may be arranged to be spaced apart from each other and face opposite to each other. Moreover, a plurality of reception arrays RXS1, RXS2 may be arranged to be spaced apart from each other and face opposite to each other. Moreover, a first transmission array TXS1 and a second transmission array TXS2 may each be one of the plurality of transmission arrays TXS1, TXS2. Moreover, a first reception array RXS1 and a second reception array RXS2 may each be one of the plurality of reception arrays RXS1, RXS2. Moreover, the first transmission array TXS1 and the second transmission array TXS2 may each have the same size of aperture DTS*P. Moreover, the first reception array RXS1 and the second reception array RXS2 may each have the same size of aperture DRS*Q. Moreover, the first transmission array TXS1 and the second transmission array TXS2 may be spaced apart from each other by the aperture size DRS*Q of the first reception array RXS1. Moreover, the first reception array RXS1 and the second reception array RXS2 may be spaced apart from each other by the aperture size DRS*P of the first transmission array TXS1.

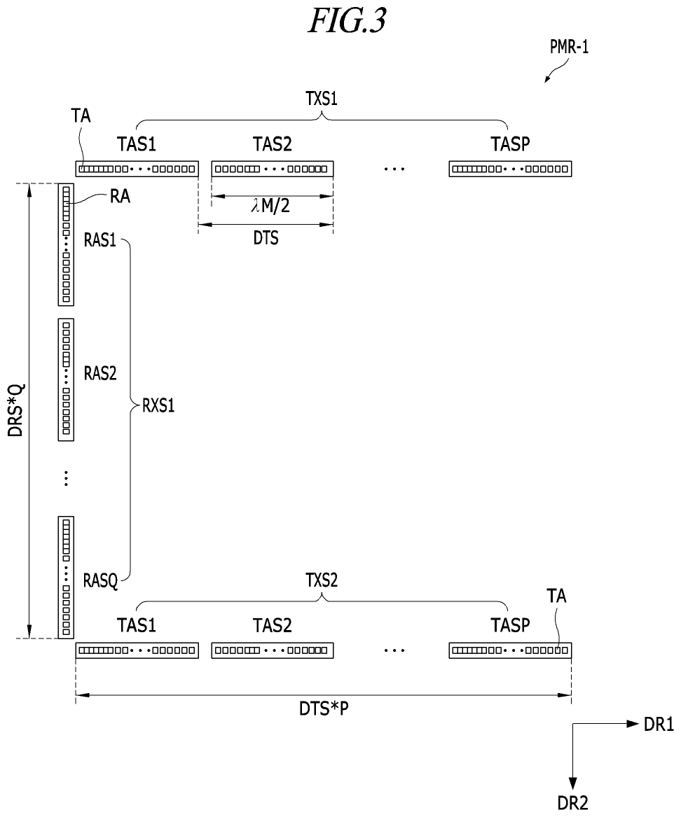

FIG. 3 illustrates a portion of a two-dimensional phased subarray MIMO radar apparatus PMR-1 in accordance with another embodiment of the present disclosure.

Referring to FIG. 3, a transmission array TXS may be provided in plurality. Moreover, a plurality of transmission arrays TXS1, TXS2 may be arranged to be spaced apart from each other and face opposite to each other. Moreover, a first transmission array TXS1 and a second transmission array TXS2 may each be one of the plurality of transmission arrays TXS1, TXS2. The first transmission array TXS1 and the second transmission array TXS2 may be spaced apart from each other by the aperture size DRS*Q of a reception array RXS. Accordingly, a virtual array (not shown) in the size of DRSQ*2DTSP may be generated. Therefore, in the two-dimensional phased subarray MIMO radar apparatus PMR-1 in accordance with another embodiment of the present disclosure, the angular resolution for a first direction DR1 may be doubled.

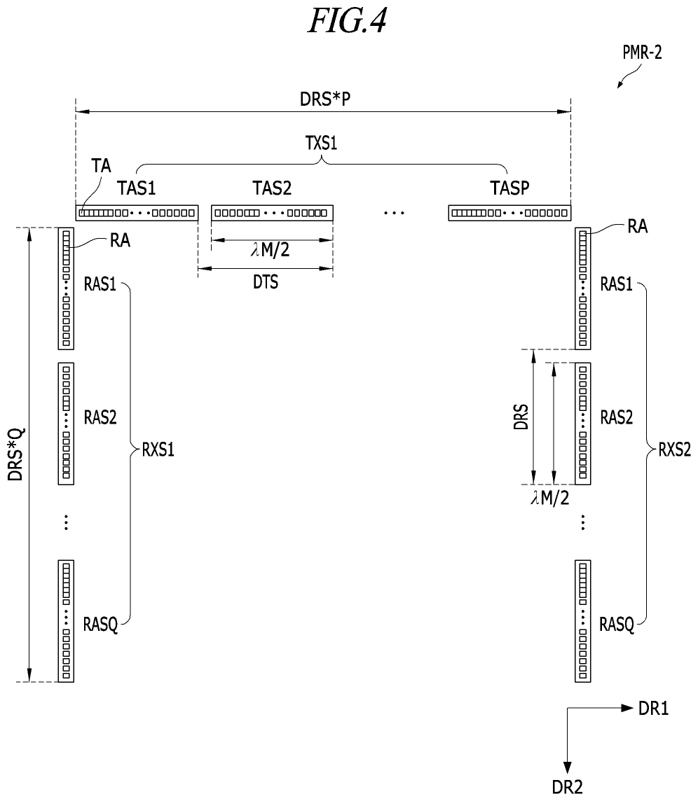

FIG. 4 illustrates a portion of a two-dimensional phased subarray MIMO radar apparatus PMR-2 in accordance with yet another embodiment of the present disclosure.

Referring to FIG. 4, a reception array RXS may be provided in plurality. Moreover, a plurality of reception arrays RXS1, RXS2 may be arranged to be spaced apart from each other and face opposite to each other. Moreover, a first reception array RXS1 and a second reception array RXS2 may each be one of the plurality of reception arrays RXS1, RXS2. The first reception array RXS1 and the second reception array RXS2 may be spaced apart from each other by the aperture size DTS*P of a transmission array TXS. Accordingly, a virtual array (not shown) in the size of 2DRSQ*DTSP may be generated. Therefore, in the two-dimensional phased subarray MIMO radar apparatus PMR-2 in accordance with yet another embodiment of the present disclosure, the angular resolution for a second direction DR2 may be doubled.

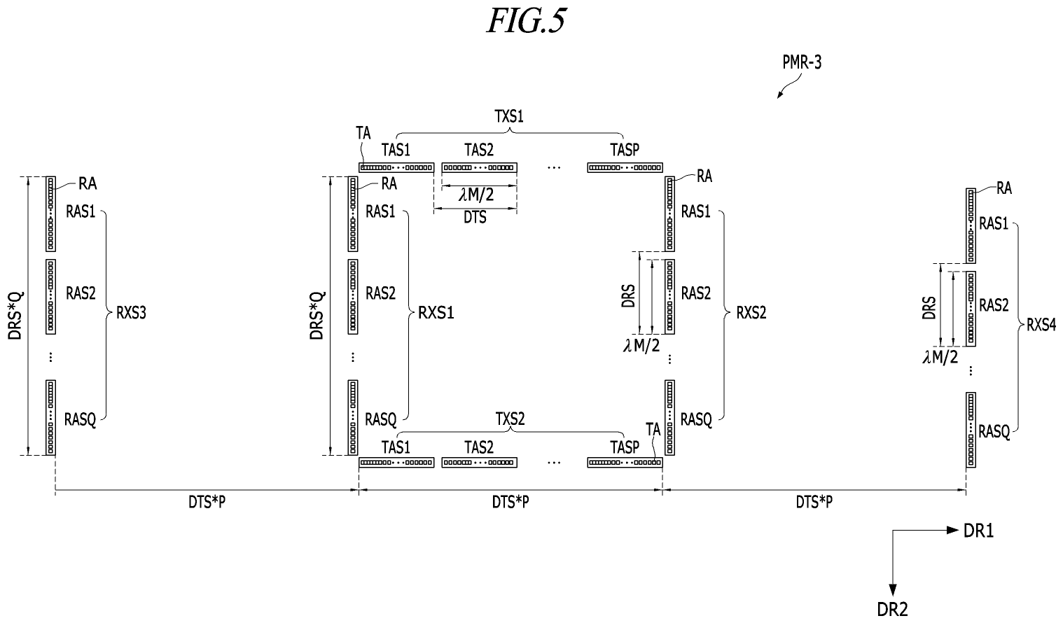

FIG. 5 illustrates a portion of a two-dimensional phased subarray MIMO radar apparatus PMR-3 in accordance with still another embodiment of the present disclosure. A transmission array TXS and a reception array RXS may each be provided in plurality. Moreover, a plurality of transmission arrays TXS1, TXS2 may be arranged to be spaced apart from each other and face opposite to each other. Moreover, a plurality of reception arrays RXS1, RXS2, RXS3, RXS4 may be arranged to be spaced apart from each other and face opposite to each other. Moreover, the plurality of transmission arrays TXS1, TXS2 may each have the same size of aperture DTS. Moreover, the plurality of reception arrays RXS may each have the same size of aperture DRS. Moreover, two adjacent transmission arrays TXS1, TXS2 among the plurality of transmission arrays TXS may be spaced apart from each other by the aperture size DRS*Q of the reception array RXS. Moreover, two adjacent reception arrays among the plurality of reception arrays RXS1, RXS2, RXS3, RXS4 may be spaced apart from each other by the aperture size DTS*P of the transmission array TXS. Accordingly, a virtual array (not shown) in the size of 4DRSQ*2DTSP may be generated. Therefore, in the two-dimensional phased subarray MIMO radar apparatus PMR-3 in accordance with still another embodiment of the present disclosure, the angular resolution for a first direction DR1 may be quadrupled. Moreover, the angular resolution for a second direction DR2 may be doubled.

While it is illustrated in FIG. 5 that the two-dimensional phased subarray MIMO radar apparatus PMR-3 includes 2 transmission arrays TXS1, TXS2 and 4 reception arrays RXS1, RXS2, RXS3, RXS4, the number of the transmission arrays and reception arrays is merely an example, and it shall be appreciated that the number of the transmission arrays TXS and the number of the reception arrays RXS may not be limited to what is illustrated in FIG. 5.

As illustrated in and described with reference to FIGS. 3 to 5, a two-dimensional phased subarray MIMO radar with improved angular resolution in a particular direction may be implemented by using the embodiments PMR-1, PMR-2, PMR-3 of the present disclosure. Therefore, the users may properly increase or decrease the number of the transmission arrays TXS and reception arrays RXS according to technical requirements to economically implement a MIMO radar apparatus.

FIG. 6 illustrates a portion of the transmission array TXS and transmission circuit TXC of the two-dimensional phased subarray MIMO radar apparatus PMR in accordance with an embodiment of the present disclosure. FIG. 7 illustrates a portion of the reception array RXS and reception circuit RXC of the two-dimensional phased subarray MIMO radar apparatus PMR in accordance with an embodiment of the present disclosure.

The transmission circuit TXC and the reception circuit RXC may each include a plurality of phase shifters PHS1, PHS2. Moreover, the transmission circuit TXC and the reception circuit RXC may each cancel some of grating lobes of a virtual subarray beam pattern by steering a transmission subarray beam pattern and a reception subarray beam pattern based on weights applied to the plurality of phase shifters PHS1, PHS2. The weights applied to the plurality of phase shifters PHS1, PHS2 may be included in the first control signal CTL1 and the second control signal CTL2.

Referring to FIG. 1 and FIG. 6, the transmission circuit TXC may include a plurality of first phase shifters PHS1 corresponding, respectively, to the plurality of transmission antennas TA1, TA2, . . . , TAM. Moreover, the transmission circuit TXC may be configured to perform hybrid beamforming. In this process, the transmission circuit TXC may be configured to steer the transmission subarray beam pattern of the plurality of transmission phased subarrays TAS1, TAS2, . . . , TASQ based on the weights applied to the plurality of first phase shifters PHS1.

In an embodiment of the present disclosure, the transmission circuit TXC may further include a plurality of digital-to-analog converters DAC and a plurality of first mixers MX1. The plurality of digital-to-analog converters DAC may correspond, respectively, to the plurality of transmission phased subarrays TAS1, TAS2, . . . , TASQ. The plurality of digital-to-analog converters DAC may be configured to convert the input digital signal IS to the first baseband signals BS1, which are analog signals. The plurality of first mixers MX1 may correspond, respectively, to the plurality of transmission phased subarrays TAS1, TAS2, . . . , TASQ. The plurality of first mixers MX1 may be configured to convert each of the first baseband signals BS1 to an RF signal, which is a high-frequency signal. The plurality of first phase shifters PHS1 may each be configured to delay the phase of the RF signal based on the first control signal CTL1 and then provide the RF signal to one of the plurality of transmission antennas TA1, TA2, . . . , TAM.

Referring to FIG. 1 and FIG. 7, the reception circuit RXC may include a plurality of second phase shifters PHS2 corresponding, respectively, to the plurality of reception antennas RA1, RA2, . . . , RAM. Moreover, the reception circuit RXC may be configured to perform hybrid beamforming. In this process, the reception circuit RXC may be configured to steer the reception subarray beam pattern of the plurality of reception phased subarrays RAS1, RAS2, . . . , RASQ based on the weights applied to the plurality of second phase shifters PHS2.

In an embodiment of the present disclosure, the reception circuit RXC may further include a plurality of analog-to-digital converters ADC and a plurality of second mixers MX2. The plurality of second phase shifters PHS2 may each be configured to delay the phase of the reflected signals RS based on the second control signal CTL2 and then provide the reflected signals RS to the plurality of second mixers MX2. The plurality of second mixers MX2 may correspond, respectively, to the plurality of reception phased subarrays RAS1, RAS2, . . . , RASQ. The plurality of second mixers MX2 may be configured to convert the delayed reflected signals RS to the second baseband signals BS2. The plurality of analog-to-digital converters ADC may correspond, respectively, to the plurality of reception phased subarrays RAS1, RAS2, . . . , RASQ. The plurality of analog-to-digital converters ADC may be configured to convert the second baseband signals BS2, which are analog signals, to the output digital signals OS.

In an embodiment of the present disclosure, the transmission circuit TXC and the reception circuit RXC may each be provided in plurality. Moreover, the plurality of transmission circuits TXC may correspond, respectively, to the plurality of transmission phased subarrays TAS1, TAS2, . . . , TASP, and the plurality of reception circuits RXC may correspond, respectively, to the plurality of reception phased subarrays RAS1, RAS2, . . . , RASQ. That is, the control circuit CTC may be configured to steer the beam generated by the plurality of transmission phased subarrays TAS1, TAS2, . . . , TASP and the plurality of reception phased subarrays RAS1, RAS2, . . . , RASQ through the first control signal CTL1 and the second control signal CTL2.

In an embodiment of the present disclosure, the number of the digital-to-analog converters DAC may be smaller than the number of the transmission antennas TA1, TA2, . . . , TAM included in the transmission device TRM. Moreover, the number of the analog-to-digital converters ADC may be smaller than the number of the reception antennas RA1, RA2, . . . , RAM included in the reception device RCM. Accordingly, it is possible to configure the hardware in a simpler fashion, thereby allowing for an improved freedom of design.

FIG. 8 illustrates a plurality of virtual reception phased subarrays VAS generated by the two-dimensional phased subarray MIMO radar apparatus PMR in accordance with an embodiment of the present disclosure. Specifically, the plurality of virtual reception phased subarrays VAS illustrated in FIG. 8 is formed when the first transmission phased subarray TAS1, the second transmission phased subarray TAS2, the first reception phased subarray RAS1 and the second reception phased subarray RAS2 are arranged as shown in FIG. 2. This will be described in detail hereinafter with reference to FIG. 2 and FIG. 8. Referring to FIG. 8, in an embodiment of the present disclosure, the number of the transmission antennas TA1, TA2, . . . , TAM (see FIG. 2) and the number of the reception antennas RA1, RA2, . . . , RAM (see FIG. 2) may each be M. The number of the transmission phased subarrays TAS1, TAS2, . . . , TASP (see FIG. 2) may be P. The number of the reception phased subarrays RAS1, RAS2, . . . , RASQ (see FIG. 2) may be Q. Here, M, P and Q may each be an integer greater than or equal to 2. Based on the above-described second baseband signals BS2, a virtual array VRS may be formed in a matrix format. The virtual array VRS may include virtual reception phased subarrays VAS in the quantity of P*M. Each of the virtual reception phased subarrays VAS may include virtual reception antennas VA in the quantity of M*M. A virtual subarray beam pattern may be formed by the virtual reception phased subarrays VAS. That is, the size of the virtual reception phased subarrays 2DRSQ*2DTSP (see FIG. 8) may be 4 times bigger than the size of the physical aperture DRSQ*DTSP (see FIG. 2). Accordingly, the angular resolution of the two-dimensional phased subarray MIMO radar apparatus PMR in accordance with an embodiment of the present disclosure may be quadrupled.

The transmission circuit TXC may be configured to steer the transmission subarray beam pattern in a first steering direction. The reception circuit RXC may be configured to steer the reception subarray beam pattern in a second steering direction. Through the above-described processes, the transmission circuit TXC and the reception circuit RXC may cancel some of the grating lobes occurring in the virtual subarray beam pattern.

In an embodiment of the present disclosure, a first grating lobe and a second grating lobe may each be one of the grating lobes adjacent to a main lobe of the virtual subarray beam pattern. The transmission circuit TXC may align a direction of a first null point occurred in the transmission subarray beam pattern with a direction of the first grating lobe. The reception circuit RXC may align a direction of a second null point occurred in the reception subarray beam pattern with a direction of the second grating lobe. Through the above-described processes, the transmission circuit TXC and the reception circuit RXC may cancel at least a portion of the first and second grating lobes.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A two-dimensional phased subarray MIMO radar apparatus comprising:
a transmission array configured to emit transmission signals, which are orthogonal to each other, towards a target object, extending in a first direction, and comprising a plurality of transmission phased subarrays; and
a reception array configured to receive reflected signals, which are reflected from the target object, among the emitted transmission signals, extending in a second direction intersecting the first direction, and comprising a plurality of reception phased subarrays,
wherein each of the plurality of transmission phased subarrays comprises a plurality of transmission antennas, and each of the plurality of reception phased subarrays comprises a plurality of reception antennas,
wherein a first transmission phased subarray and a second transmission phased subarray are adjacent transmission phased subarrays among the plurality of transmission phased subarrays, and a spacing from an end of the first transmission phased subarray in the first direction to an end of the second transmission phased subarray in the first direction is a first spacing, the first spacing being greater than or equal to an aperture of each of the plurality of transmission phased subarrays, and
wherein a first reception phased subarray and a second reception phased subarray are adjacent reception phased subarrays among the plurality of reception phased subarray, and a spacing from an end of the first reception phased subarray in the second direction to an end of the second reception phased subarray in the second direction is a second spacing, the second spacing being greater than or equal to an aperture of each of the plurality of reception phased subarrays.

2. The two-dimensional phased subarray MIMO radar apparatus of claim 1, wherein the transmission array is provided in plurality,
wherein the plurality of transmission arrays are arranged to be spaced apart from each other and face each other, and
wherein each of a first transmission array and a second transmission array is one of the plurality of transmission arrays, and the first transmission array and the second transmission array are arranged to be spaced apart from each other by a size of an aperture of the reception array.

3. The two-dimensional phased subarray MIMO radar apparatus of claim 1, wherein the reception array is provided in plurality,
wherein the plurality of reception arrays are arranged to be spaced apart from each other and face each other, and
wherein each of a first reception array and a second reception array is one of the plurality of reception arrays, and the first reception array and the second reception array are arranged to be spaced apart from each other by a size of an aperture of the transmission array.

4. The two-dimensional phased subarray MIMO radar apparatus of claim 1, wherein each of the transmission array and the reception array is provided in plurality,
wherein the plurality of transmission arrays are arranged to be spaced apart from each other and face each other, and the plurality of reception arrays are arranged to be spaced apart from each other and face each other,
wherein each of a first transmission array and a second transmission array is one of the plurality of transmission arrays, and each of a first reception array and a second reception array is one of the plurality of reception arrays,
wherein the first transmission array and the second transmission array have the same size of aperture, and the first reception array and the second reception array have the same size of aperture,
wherein the first transmission array and the second transmission array are arranged to be spaced apart from each other by the size of the aperture of the first reception array, and
wherein the first reception array and the second reception array are arranged to be spaced apart from each other by the size of the aperture of the first transmission array.

5. The two-dimensional phased subarray MIMO radar apparatus of claim 4, further comprising:
a transmission circuit comprising a plurality of first phase shifters corresponding, respectively, to the plurality of transmission antennas and configured to perform hybrid beamforming by steering a transmission subarray beam pattern of the plurality of transmission phased subarrays based on weights applied to the plurality of first phase shifters; and
a reception circuit comprising a plurality of second phase shifters corresponding, respectively, to the plurality of reception antennas and configured to perform hybrid beamforming by steering a reception subarray beam pattern of the plurality of reception phased subarrays based on weights applied to the plurality of second phase shifters.

6. The two-dimensional phased subarray MIMO radar apparatus of claim 5, further comprising a control circuit configured to generate an input digital signal, a first control signal for controlling the transmission circuit and a second control signal for controlling the reception circuit,
wherein the transmission circuit further comprises a plurality of digital-to-analog converters and a plurality of first mixers,
wherein the plurality of digital-to-analog converters correspond, respectively, to the plurality of transmission phased subarrays and are configured to convert the input digital signal to first baseband signals, the first baseband signals being analog signals,
wherein the plurality of first mixers correspond, respectively, to the plurality of transmission phased subarrays and are configured to convert each of the first baseband signals to an RF signal, the RF signal being a high-frequency signal,
wherein each of the plurality of first phase shifters is configured to delay a phase of the RF signal based on the first control signal and then provide the RF signal to one of the plurality of transmission antennas,
wherein the reception circuit further comprises a plurality of analog-to-digital converters and a plurality of second mixers,
wherein each of the plurality of second phase shifters is configured to delay a phase of the reflected signals based on the second control signal and then provide the reflected signals to the plurality of second mixers,
wherein the plurality of second mixers correspond, respectively, to the plurality of reception phased subarrays and are configured to convert the delayed reflected signals to second baseband signals, and
wherein the plurality of analog-to-digital converters correspond, respectively, to the plurality of reception phased subarrays and are configured to convert the second baseband signals to output digital signals, the second baseband signals being analog signals.

7. The two-dimensional phased subarray MIMO radar apparatus of claim 6, wherein the number of each of the transmission antennas and the reception antennas is M, and the number of the transmission phased subarrays is P, and the number of the reception phased subarrays is Q, whereas M, P and Q are each an integer greater than or equal to 2,
wherein, based on the second baseband signals, 2P*2M virtual reception phased subarrays are formed in a matrix format, and each of the virtual reception phased subarrays comprises M*M virtual reception antennas, and a virtual subarray beam pattern is formed by the virtual reception phased subarrays, and
wherein the transmission circuit is configured to steer the transmission subarray beam pattern in a first steering direction, and the reception circuit is configured to steer the reception subarray beam pattern in a second steering direction, thereby cancelling some of grating lobes occurred in the virtual subarray beam pattern.

8. The two-dimensional phased subarray MIMO radar apparatus of claim 7, wherein each of a first grating lobe and a second grating lobe is one of the grating lobes adjacent to a main lobe of the virtual subarray beam pattern, and
wherein the transmission circuit is configured to align a direction of a first null point occurred in the transmission subarray beam pattern with a direction of the first grating lobe, and the reception circuit is configured to align a direction of a second null point occurred in the reception subarray beam pattern with a direction of the second grating lobe of the grating lobes, thereby cancelling some of the first and second grating lobes.

9. The two-dimensional phased subarray MIMO radar apparatus of claim 8, wherein a spacing between two adjacent transmission antennas among the plurality of transmission antennas and a spacing between two adjacent reception antennas among the plurality of reception antennas are each equal to a half-wavelength of the transmission signals.

10. The two-dimensional phased subarray MIMO radar apparatus of claim 1, wherein each of the transmission array and the reception array is provided in plurality,
wherein the plurality of transmission arrays are arranged to be spaced apart from each other and face each other,
wherein the plurality of reception arrays are arranged to be spaced apart from each other and face each other,
wherein the plurality of transmission arrays have the same size of aperture, and the plurality of reception arrays have the same size of aperture,
wherein two adjacent transmission arrays among the plurality of transmission arrays are arranged to be spaced apart from each other by the size of the aperture of the reception array, and
wherein two adjacent reception arrays among the plurality of reception arrays are arranged to be spaced apart from each other by the size of the aperture of the transmission array.
